(19) United States
(12) Patent Application Publication
(10) Pub. No.: US 2026/0313778 A1
(43) Pub. Date: Oct. 8, 2026

(54) Electrostatic Discharge Protection

(71) Applicant: Sensor Electronic Technology, Inc., Columbia, SC (US)

(72) Inventor: Piyush Sharma, Columbia, SC (US)

(21) Appl. No.: 19/460,759

(22) Filed: Jan. 27, 2026

Related U.S. Application Data
(60) Provisional application No. 63/752,210, filed on Jan. 31, 2025.

(51) Int. Cl. H05F 3/06; H05K 7/14

(52) U.S. Cl. CPC H05F 3/06; H05K 7/1488

(57) ABSTRACT

An electrostatic discharge (ESD) protection system including an ionizing light source configured to emit ionizing light directed in an area and a control component configured to operate the ionizing light source to reduce risk of an ESD event in the area. The system also can include an electrostatic sensor configured to acquire electrostatic data, and which can be associated with an ESD sensitive object. The control component can use the electrostatic data to operate the ionizing light source based on a determined likelihood of an ESD event. The ESD protection system can be configured for use in a data center, where one or more data center racks can include an electrostatic sensor and/or ionizing light source.

### REFERENCE TO RELATED APPLICATIONS

The current application claims the benefit of U.S. Provisional Application 63/752,210, filed on 31 Jan. 2025, which is hereby incorporated by reference.

### TECHNICAL FIELD

The disclosure relates generally to electrostatic discharge (ESD) protection, and more particularly, to ESD protection using ultraviolet-C radiation.

### BACKGROUND ART

In today's technology-driven industries, particularly in sectors involving high-performance electronics such as data centers, artificial intelligence (AI) processing hubs, supercomputing facilities, and semiconductor manufacturing plants, electrostatic discharge (ESD) is a persistent and critical problem. ESD occurs when an electric charge accumulated on a surface or within the air discharges onto another object. Given the increasing miniaturization and complexity of sensitive components, such as microchips and processors, the impact of even minor ESD events on these components can be catastrophic, leading to component failures, degraded system performance, and costly downtime.

Data centers, where servers and processors continuously handle vast amounts of information, are particularly vulnerable. Each year, ESD-related damages cost the industry billions due to unexpected system failures, downtime, and reduced component lifespans. As processing power increases, so does the sensitivity of electronics to static charges, making ESD control not just an operational consideration but a business-critical requirement.

Manufacturing environments, particularly in semiconductor fabrication, also experience significant risks from ESD. Cleanrooms and assembly lines need stringent anti-static measures to protect the microscopic circuitry of the chips. Even a small discharge can corrupt data or damage silicon wafers, leading to defective products and a loss of production yield.

Current approaches to manage and mitigate static buildup typically involve large-scale or localized ionization systems, antistatic materials, and humidity control. Each approach aims to neutralize or dissipate static charges, but each approach includes several shortcomings.

HVAC systems in many modern data centers and processing hubs often incorporate air ionizers to reduce the static charge by releasing positive and negative ions into the air. These ions neutralize the charges on dust particles and air molecules, helping reduce overall static buildup in large spaces. These systems treat the air in bulk, which may not provide sufficient localized control over the areas where static discharge pose the highest risk—such as near sensitive electronics, server racks, or semiconductor wafers. Moreover, HVAC-based ionizers require extensive infrastructure investment and are not easily customizable for targeting specific hotspots of static buildup.

Manufacturing facilities and data centers often use antistatic coatings or ESD mats on surfaces to reduce static buildup. These mats and coatings can safely discharge static by providing a grounding mechanism that channels the charge away from sensitive components. These solutions are limited to surface-level protection. They do not address the potential for airborne static charges or fluctuating environmental factors that increase the risk of ESD. Furthermore, coatings and mats degrade over time, losing their effectiveness and requiring regular maintenance or replacement.

Another approach involves controlling the relative humidity (RH) in the environment to prevent static buildup. By maintaining the relative humidity above 40%, the risk of static generation is reduced, as higher moisture levels increase air conductivity and help dissipate static charges. Maintaining optimal humidity levels across large areas like data centers is not always feasible or cost-effective. Additionally, this approach only offers indirect control of static electricity, and the response to changes in static charge levels can be slow or ineffective in critical environments.

In many cleanrooms or semiconductor manufacturing facilities, standalone ionizers or ionization fans are used to generate ionized air near sensitive equipment. These devices are effective at neutralizing airborne static but require manual adjustments and frequent calibration to ensure optimal performance. These systems are non-automated and provide limited real-time control of static charge levels. They are also not integrated with existing environmental control systems, leading to inefficiencies and increased energy consumption.

### SUMMARY OF THE INVENTION

Aspects of the invention provide an ESD protection system, which can provide specific targeting of high risk area(s) for static buildup. Embodiments can provide a focused, modular approach to ESD mitigation that minimizes ESD risk precisely where such mitigation is needed most. The ESD protection system can include an ionizing light source configured to emit ionizing light directed in an area and a control component configured to operate the ionizing light source to reduce risk of an ESD event in the area. The ESD protection system also can include an electrostatic sensor configured to acquire electrostatic data, and which can be associated with an ESD sensitive object. The control component can use the electrostatic data to operate the ionizing light source based on a determined likelihood of an ESD event.

Embodiments can provide precision control and/or dynamic response to prevent electrostatic discharge (ESD) before it reaches damaging levels.

Embodiments can include integrated electrostatic sensors, which can continuously monitor electrostatic conditions on surfaces and/or in the environment. A control component can dynamically adjust an intensity of ionizing light based on real-time readings of the electrostatic conditions. To this extent, embodiments can provide a feedback-driven, automated operation, which can optimize ionization levels, prevent static buildup, and/or the like, without manual intervention.

By targeting specific area(s) and adjusting ionizing light intensity in real-time, embodiments can consume less energy than large-scale HVAC ionization solutions, which typically run at a constant level. Embodiments can use ultraviolet LEDs to generate the ionizing light, which can further enhance energy savings over traditional air ionizers, thereby providing a cost-effective solution for various applications, such as data centers, semiconductor environments, and/or the like.

Embodiments of the system can be implemented with a modular, scalable design, which can allow for easy integration into existing infrastructure without large-scale modifications. Unlike HVAC ionizers, embodiments of the system can be deployed precisely where needed, making it ideal for targeted static control, from large data centers to specific chip fabrication stations and other applications.

By effectively preventing ESD events, embodiments of the system can safeguard ESD sensitive objects, which can reduce costly repairs and downtime. Additionally, the use of a non-contact solution based on ionizing light provides a solution with no physical wear on components, thereby eliminating the need for regular replacement of ESD protection devices, such as mats or antistatic coatings, and significantly lowering long-term maintenance costs.

Embodiments of the solution can be implemented alone or in conjunction with any of the existing solutions for preventing ESD events.

Embodiments of the ESD protection system can be configured for use in a data center, where one or more data center racks can include an electrostatic sensor and/or ionizing light source.

A first aspect of the invention provides an electrostatic discharge (ESD) protection system comprising: an electrostatic sensor configured to be associated with an ESD sensitive object; a control component configured to receive electrostatic data acquired by the electrostatic sensor and determine a likelihood of an ESD event using the electrostatic data; and an ionizing light source configured to emit ionizing light directed in an area near the ESD sensitive object, wherein the control component is configured to activate the ionizing light source to emit the ionizing light in response to a determination that the likelihood of the ESD event exceeds a predetermined threshold.

A second aspect of the invention provides an electrostatic discharge (ESD) protection system for an environment including an ESD sensitive object, the ESD protection system comprising: a plurality of ionizing light sources, wherein each of the plurality of ionizing light sources is configured to emit ionizing light directed in an area of the environment; and a control component configured to operate the plurality of ionizing light sources to reduce risk of an ESD event in the environment.

A third aspect of the invention provides a data center comprising: a data center control system configured to manage operation of the data center and maintain an environment within the data center; and a plurality of data center racks, at least one of the plurality of data center racks including: a plurality of shelves, each shelf configured to hold at least one ESD sensitive computing component; at least one electrostatic sensor associated with at least one of the plurality of shelves, wherein the at least one electrostatic sensor is configured to acquire electrostatic data; and an ionizing light source configured to emit ionizing light directed in an area near the at least one of the plurality of shelves, wherein an ESD control component is configured to determine a likelihood of an ESD event using the electrostatic data and activate the ionizing light source to emit the ionizing light in response to a determination that the likelihood of the ESD event exceeds a predetermined threshold.

A fourth aspect of the invention provides a method of preventing an electrostatic discharge (ESD) event associated with an ESD sensitive object, the method comprising: acquiring, on a control component, electrostatic data associated with the object; determining, by the control component, a likelihood of an electrostatic discharge event based on the electrostatic data; and the control component activating an ionizing light source to emit ionizing light in a region proximate the object when the likelihood exceeds a predetermined threshold.

The illustrative aspects of the invention are designed to solve one or more of the problems herein described and/or one or more other problems not discussed.

### BRIEF DESCRIPTION OF THE DRAWINGS

These and other features of the disclosure will be more readily understood from the following detailed description of the various aspects of the invention taken in conjunction with the accompanying drawings that depict various aspects of the invention.

FIG. 1 shows a schematic of an illustrative electrostatic discharge (ESD) protection system according to embodiments.

FIG. 2 shows an illustrative data center including an ESD protection system according to embodiments.

FIG. 3 shows a schematic of an illustrative power and control system for a data center including an ESD protection component according to embodiments.

FIGS. 4A and 4B show a front view of an illustrative rack and a side view of an internal surface of an illustrative side panel of the rack according to embodiments.

FIG. 5 shows an illustrative component shelf for a rack, which includes an ESD protection system according to embodiments.

FIG. 6 shows an illustrative ionizing light source configuration according to embodiments.

FIG. 7 shows an illustrative vent including an ESD protection system according to embodiments.

FIG. 8 shows an illustrative process for protecting an ESD sensitive object from an ESD event, which can be implemented by an ESD protection control component described herein, according to embodiments.

It is noted that the drawings may not be to scale. The drawings are intended to depict only typical aspects of the invention, and therefore should not be considered as limiting the scope of the invention. In the drawings, like numbering represents like elements between the drawings.

### DETAILED DESCRIPTION OF THE INVENTION

As indicated above, aspects of the invention provide an ESD protection system, which can provide specific targeting of high risk area(s) for static buildup. Embodiments can provide a focused, modular approach to ESD mitigation that minimizes ESD risk precisely where such mitigation is needed most.

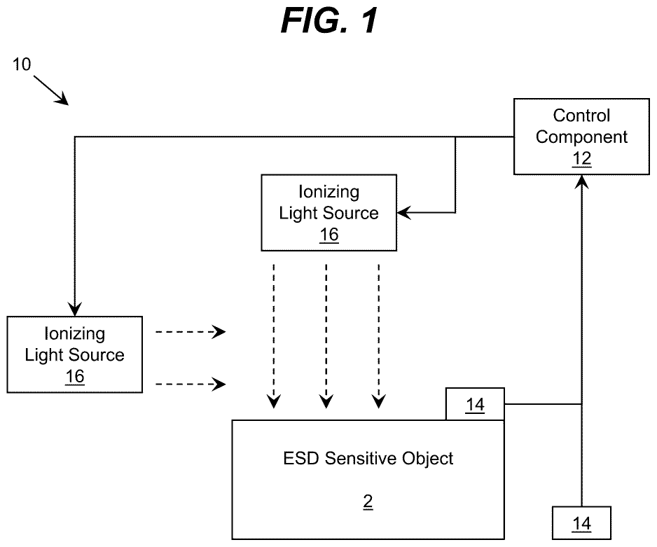

Turning to the drawings, FIG. 1 shows a schematic of an illustrative electrostatic discharge (ESD) protection system 10 according to embodiments. In general, the ESD protection system 10 is configured to prevent an accumulated electric charge within or on a surface of an object from discharging onto an ESD sensitive object 2, which may be adversely affected by the electrostatic discharge.

The ESD sensitive object 2 can comprise any type of object that may be adversely affected by an electrostatic discharge. Illustrative ESD sensitive objects 2 include microchips, processors, memory arrays, and the corresponding circuitry, semiconductor wafers, etc. Other illustrative ESD sensitive objects include printed circuit boards (PCBs), storage devices (HDDs and SSDs), optoelectronic components, medical devices, aerospace and automotive electronics, display panels (LCD, OLED, MicroLEDs), quantum computing components, MEMS (micro-electromechanical systems), lithium-ion battery management systems, etc. Each of these objects is or includes one or more components that are highly susceptible to electrostatic discharge, which can cause malfunction, degradation, or complete failure. As a result, effective ESD protection can be a critical function across various industries.

The ESD protection system 10 includes a control component 12, which can receive electrostatic data from one or more electrostatic sensors 14 associated with the ESD sensitive object 2. As illustrated, an electrostatic sensor 14 can be located on a surface of the ESD sensitive object 2, near an ESD sensitive object 2, and/or the like. A number of electrostatic sensors 14 and their corresponding locations with respect to an ESD sensitive object 2 can vary based on an application of the ESD protection system 10. As used herein, a sensor, such as an electrostatic sensor 14, is associated with a corresponding object, surface, area, and/or the like, when the electrostatic sensor 14 is located on the object or surface or within the area, or when the electrostatic sensor 14 is located sufficiently close to the object, surface, area, etc., that data acquired by the electrostatic sensor 14 corresponds sufficiently to the corresponding object, surface, area, etc., to provide data relevant for providing ESD protection for the corresponding object, surface, area, etc., as described herein. In embodiments, the ESD protection system 10 can include a plurality of electrostatic sensors 14 spatially distributed around the ESD sensitive object 2.

An electrostatic sensor 14 can acquire electrostatic data relating to a likelihood of an electrostatic discharge event using any solution. In embodiments, the electrostatic sensor 14 can acquire electrostatic data, which can include a measurement of an electric field strength or surface voltage related to the static charge or the like. In embodiments, an electrostatic sensor 14 can acquire electrostatic data relating to an environment of the ESD sensitive object 2 using any solution. For example, an electrostatic sensor 14 can acquire electrostatic data corresponding to a humidity (e.g., a relative humidity), a temperature, and/or the like, of the ambient environment for the ESD sensitive object 2. Other illustrative electrostatic data that can be acquired by an electrostatic sensor 14 include an air ionization level, an electrostatic potential distribution, a charge decay rate, and/or the like, each of which influences static buildup and dissipation. Embodiments of an electrostatic sensor 14 also can acquire electrostatic data corresponding to a material conductivity or resistivity, detect airflow, detect charged airborne particles, acquire data corresponding to triboelectric charging events caused by friction, and/or the like.

The control component 12 can receive the electrostatic data from the electrostatic sensor(s) 14 and determine whether a risk of an ESD event exceeds a predetermined level using any solution. For example, the control component 12 can determine whether the measured electric field strength or surface voltage exceeds a predetermined acceptable level of electric field strength or surface voltage. Furthermore, the control component 12 can consider the electrostatic data relating to the environment, such as the measured humidity level, temperature, and/or the like, in determining an acceptable level of electric field strength or surface voltage. Embodiments of the control component 12 can process various combinations and/or types of electrostatic data to determine a comprehensive understanding of the electrostatic environment, thereby enabling more effective ESD prevention and control.

In embodiments, the control component 12 can dynamically adjust one or more aspects of operation based on data corresponding to past ESD events. For example, one or more of the predetermined level of risk, predetermined acceptable level of electric field strength or surface voltage, and/or the like, can be adjusted up or down based on historical data relating to ESD events in a current ambient environment and/or in environments sufficiently similar to the current ambient environment. In embodiments, the control component 12 can determine the likelihood of an ESD event using a predictive model trained on the historical data relating to ESD events. In embodiments, the predictive model can be periodically retrained using additional historical data.

In embodiments, the control component 12 also can adjust one or more of the predetermined level of risk, predetermined acceptable level of electric field strength or surface voltage, and/or the like, based on the environmental conditions, a type of ESD sensitive object being protected, and/or the like. Adjustment of predetermined values to adaptive thresholds can enable the control component 12 to increase safety for ultra-sensitive components and also prevent nuisance alarms and unnecessary downtime when handling more robust items. The control component 12 can function as a dynamic engine, which can calculate a safety margin that can shift in real-time.

Different ESD sensitive objects 2 can have different ESD sensitivity classes. In embodiments, the control component 12 can identify an ESD sensitive object 2 in a location, e.g., via RFID, barcode, manual setting, and/or the like. The control component 12 then can adjust a threshold based on a corresponding ESD sensitivity for the ESD sensitive object 2. For example, the control component 12 can store a table of a maximum withstand voltage for various ESD sensitive objects 2 that may be located within a protected area. The contents of the table can be based on industry standards, such as ANSI, ESDA, JEDEC JS-001 (for Human Body Model), and/or the like. When the control component 12 determines that the ESD sensitive object 2 is a Class 0A device (<125V sensitivity), the control component 12 can automatically reduce the predetermined threshold to increase a level of protection. In contrast, when the control component 12 determines that the ESD sensitive object 2 is a Class 2 device (2000V to 4000V), the control component 12 can increase the predetermined threshold to reduce unnecessary operation of ionizing light sources 16, false alarms, etc.

When the control component 12 determines that the electrostatic data indicates a sufficiently high risk of an ESD event, the control component 12 can activate one or more ionizing light sources 16 to ionize the air surrounding ESD sensitive object 2, which in turn neutralizes both positive and negative static charges on surfaces and in the air and the electric field strength/surface voltage on the ESD sensitive object 2. As illustrated, an ionizing light source 16 can emit ionizing light directed onto a surface of the ESD sensitive object 2 or an ionizing light source 16 can emit ionizing light that is directed in an area near the ESD sensitive object 2.

The ionizing light emitted by the ionizing light source(s) 16 can comprise any light that is capable of ionizing air molecules, which in turn neutralizes positive and negative static charges on surfaces and in the air. In embodiments, the ESD protection system 10 includes one or more ionizing light sources 16 that emit ultraviolet light. In more particular embodiments, at least one ionizing light source 16 emits ultraviolet light having a peak wavelength in the ultraviolet-C range of wavelengths. In still more particular embodiments, the peak wavelength is in a range between approximately 250 nanometers and 280 nanometers. In more particular embodiments, at least one ionizing light source 16 emits ultraviolet light having a peak wavelength in the near ultraviolet range of wavelengths. In still more particular embodiments, the peak wavelength is in a range between approximately 300 nanometers and 320 nanometers.

In embodiments, an ionizing light source 16 comprises one or more ultraviolet light emitting diodes, each of which is configured to emit ultraviolet radiation having a desired peak wavelength. In embodiments, the ESD protection system 10 can include multiple ionizing light sources 16 that emit different types of ionizing light (e.g., different peak wavelengths of ultraviolet light) and/or include a single ionizing light source 16 that emits different types of ionizing light.

In embodiments, the control component 12 controls operation of the ionizing light sources 16 to emit ionizing light in a manner that is configured to control ion density in the ambient environment of the ESD sensitive object 2. For example, the control component 12 can operate the ionizing light sources 16 to emit ionizing light in a pulsed or modulated manner. Pulsed or modulated operation can provide significant advantages in precision, safety, equipment longevity, etc. In an ESD-sensitive environment, the goal is to maintain an ionization charge that is dense enough to neutralize static charges quickly, but not so dense that it leads to excessive recombination or unnecessary radiation exposure. By operating the ionizing light sources 16 at a lower duty cycle, a lower average ion density can be maintained for stable environments. Alternatively, the duty cycle of the ionizing light sources 16 can be increased for high-speed neutralization when a highly charged object enters the protected area.

A major challenge in ionization is recombination, where positive and negative ions collide and neutralize each other before they reach the target. In continuous operation of the ionizing light sources 16 at high intensity, a high density of ions can lead to a high recombination rate, which can increase inefficiency. Operating the ionizing light sources 16 in a pulsed manner can allow ions to disperse and work on the target surface before a next wave of ions is generated, effectively improving the neutralization efficiency. Additionally, ionizing light sources 16, such as UV-LEDs, have finite lifespans. Pulsed operation can allow the ionizing light sources 16 to cool between flashes, slowing degradation. For example, operating at a 50% duty cycle can nearly double an operational life of an ionizing light source 16 compared to 100% continuous use.

It is understood that the ESD protection system 10 is only illustrative of various possible configurations of an ESD protection system according to embodiments. For example, an ESD protection system can be implemented without any electrostatic sensors 14. In this case, the control component 12 can be configured to operate the ionizing light source(s) 16 according to predetermined cycles in which the ionizing light source(s) 16 are periodically activated and deactivated. In embodiments, one or more aspects of the operation of the ionizing light source(s) 16 by the control component 12 can be configured by a user, e.g., via an interface managed by the control component 12.

In embodiments, the ESD protection system 10 also can include one or more devices that the control component 12 can operate to affect an environment of the ESD sensitive object 2. For example, embodiments of the ESD protection system 10 can include a fan, which the control component 12 can operate to selectively circulate air around the ESD sensitive object 2. Furthermore, as described herein, embodiments of the ESD protection system 10 can include various other I/O devices which can enable the control component 12 to operate safely around humans, obtain additional information about the environment, provide information to users, etc.

Additional details of embodiments of the invention are further described in conjunction with a data center as an illustrative application. However, it is understood that the data center application is only illustrative of various applications of embodiments of the ESD protection system described herein.

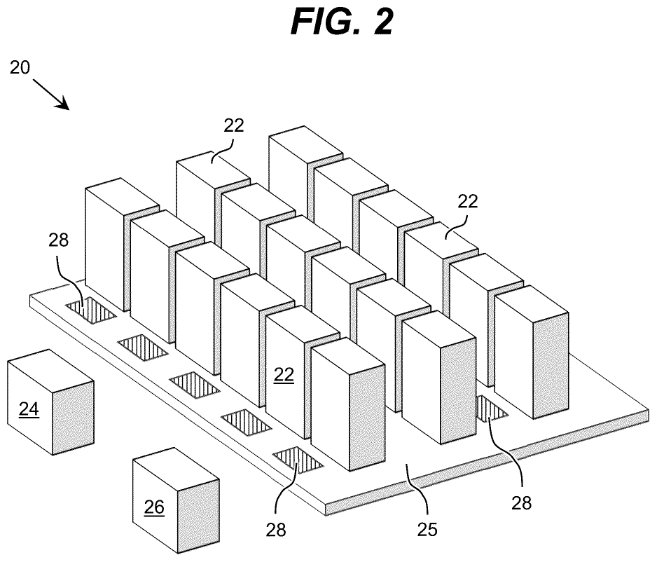

FIG. 2 shows an illustrative data center 20 including an ESD protection system according to embodiments. The data center 20 can include a plurality of racks 22, each of which can include various ESD sensitive computing components, such as servers, routers, switches, and/or the like. As continuous operation of the data center 20 is often desired, the data center 20 also can include a power system 24 that powers operation of the data center 20. The power system 24 can be connected to the power grid and also include an uninterruptable power supply, generator(s), and/or the like, in the event of a power outage.

The data center 20 also can include a data center control system 26, which can be powered by the power system 24, and operate to monitor operation of the data center 20, maintain a suitable environment within the data center 20 for operations (e.g., by heating and/or cooling the data center 20 as needed), and/or the like. As operation of the data center 20 can generate a significant amount of heat, the data center 20 can include a raised floor 25 on which the racks 22 are located. The data center control system 26 can generate and circulate cool air through ducts located below the raised floor 25 and vents 28 located in the raised floor 25. The racks 22 and vents 28 can be arranged to provide efficient cooling of the data center 20.

The data center 20 can include one or more ESD protection systems configured to prevent electrostatic discharge from damaging one or more electronic components in the racks 22. In embodiments, the data center 20 includes an ESD protection system integrated with an existing management system, such as the data center control system 26.

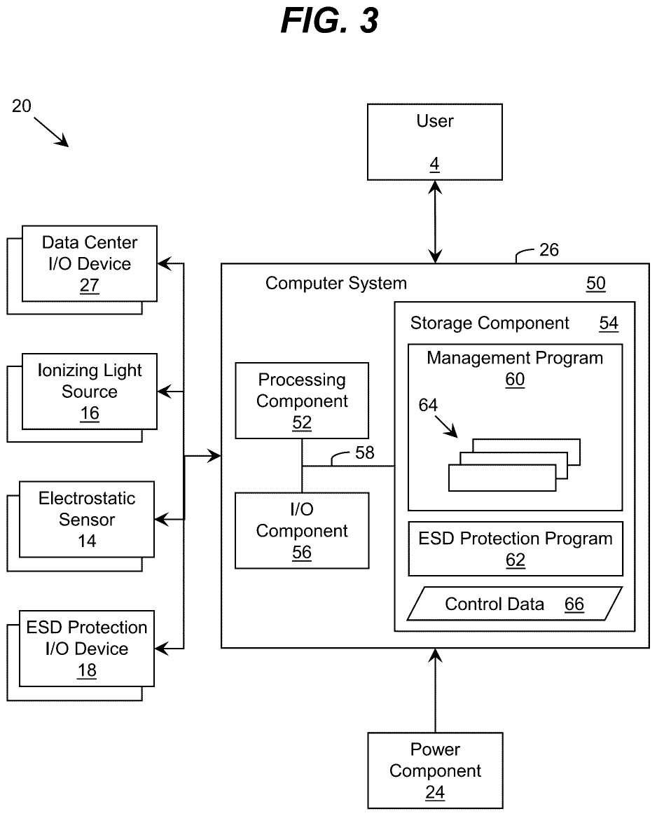

FIG. 3 shows a schematic of an illustrative power and control system for a data center 20 including an ESD protection component according to embodiments. As illustrated, the data center 20 can include various data center I/O devices 27, which acquire data for and/or are controlled by a data center control system 26. Illustrative data center I/O devices 27 can include temperature sensors, air flow sensors, fans, heating and/or cooling elements, power sensors, network communications monitors, and/or the like. The data center control system 26 is schematically illustrated as being implemented as a computer system 50 that can perform a process for monitoring operation of the data center, maintaining a suitable environment within the data center 20 for the operations thereof, and/or the like. In particular, the computer system 50 is shown including a management program 60, which makes the computer system 50 operable to monitor operation of the data center 20, maintain the environment within the data center 20, and/or the like, using any solution.

Furthermore, the computer system 50 is shown including an ESD protection program 62, which is configured to protect one or more ESD sensitive components in the data center 20 from an ESD event. To this extent, the ESD protection program 62 enables the computer system 50 to perform a process described herein in order to protect the ESD sensitive component(s) from an ESD event using ionizing light generated by one or more ionizing light sources 16.

To this extent, the computer system 50 can receive electrostatic data from one or more electrostatic sensors 14. The computer system 50 can process the electrostatic data and operate ionizing light source(s) 16 based on the electrostatic data. Additionally, the computer system 50 can receive and perform operating instructions provided by a user 4 and/or communicate information regarding an operating status of one or more components of the ESD protection system for presentation to the user 4. For a user 4 located within the data center 20, the ESD protection system can include one or more ESD protection input/output devices 18, which can receive data regarding the presence of the user 4, obtain operating data from the user 4, provide ESD data to the user 4, and/or the like.

The computer system 50 is schematically illustrated as including a processing component 52 (e.g., one or more processors), a storage component 54 (e.g., a storage hierarchy), an input/output (I/O) component 56 (e.g., one or more I/O interfaces and/or devices), and a communications pathway 58. In general, the processing component 52 executes program code, such as the management program 70 and the ESD protection program 62, which is at least partially fixed in storage component 54. While executing program code, the processing component 52 can process data, which can result in reading and/or writing transformed data, such as control data 66, from/to the storage component 54 and/or the I/O component 56 for further processing. The pathway 58 provides a communications link between each of the components in the computer system 50.

The I/O component 56 can comprise and/or communicate with one or more human I/O devices, which enable a human user 4 to interact with the computer system 50 and/or one or more communications devices to enable a system user 4 (e.g., a portable computing device of a human user, such as a mobile phone executing an app) to communicate with the computer system 50 using any type of communications link. To this extent, the management program 60 and/or the ESD protection program 62 can manage a set of interfaces (e.g., graphical user interface(s), application program interface, and/or the like) that enable human and/or system users 4 to interact with the management program 60 and/or the ESD protection program 62 and the control data 66, etc. Furthermore, the management program 60 and/or the ESD protection program 62 can manage (e.g., store, retrieve, create, manipulate, organize, present, etc.) the control data 66 using any solution.

In any event, the computer system 50 can comprise one or more general purpose computing articles of manufacture (e.g., computing devices) capable of executing program code, such as the management program 60 and/or the ESD protection program 62, installed thereon. As used herein, it is understood that “program code” means any collection of instructions, in any language, code or notation, that cause a computing device having an information processing capability to perform a particular action either directly or after any combination of the following: (a) conversion to another language, code or notation; (b) reproduction in a different material form; and/or (c) decompression. To this extent, the management program 60 and/or the ESD protection program 62 can be embodied as any combination of system software and/or application software.

Furthermore, the management program 60 and/or the ESD protection program 62 can be implemented using a set of modules 64. In this case, a module 64 can enable the computer system 50 to perform a set of tasks used by the management program 60, and can be separately developed and/or implemented apart from other portions of the treatment program 60. To this extent, embodiments of the ESD protection program 62 can be implemented as a module 64 of the management program 60. As used herein, the term “component” means any configuration of hardware, with or without software, which implements the functionality described in conjunction therewith using any solution, while the term “module” means program code that enables a computer system 50 to implement the actions described in conjunction therewith using any solution. Regardless, it is understood that two or more components, modules, and/or systems may share some/all of their respective hardware and/or software. Furthermore, it is understood that some of the functionality discussed herein may not be implemented or additional functionality may be included as part of the computer system 50.

When the computer system 50 comprises multiple computing devices, each computing device can have only a portion of the management program 60 and/or the ESD protection program 62 fixed thereon (e.g., one or more modules 64). In embodiments, the computer system 50 can comprise a computing unit which can be installed at the data center 20 and another computing unit, such as a remotely located computing device, a mobile phone, and/or the like, which is executing an app installed thereon for enabling a user 4 to monitor, evaluate, manage, and/or the like, operation of the data center 20. In embodiments, multiple computing units can be installed at the data center 20, each of which can operate independently or cooperatively with another computing unit to perform one or more actions described herein.

However, it is understood that the computer system 50 and the management program 60 and/or the ESD protection program 62 are only representative of various possible equivalent computer systems that may perform a process described herein. To this extent, in other embodiments, the functionality provided by the computer system 50 and the management program 60 and/or the ESD protection program 62 can be at least partially implemented by one or more computing devices that include any combination of general and/or specific purpose hardware with or without program code. In each embodiment, the hardware and program code, if included, can be created using standard engineering and programming techniques, respectively.

Regardless, when the computer system 50 includes multiple computing devices, the computing devices can communicate over any type of communications link. Furthermore, while performing a process described herein, the computer system 50 can communicate with one or more other computer systems using any type of communications link. In either case, the communications link can comprise any combination of various types of optical fiber, wired, and/or wireless links; comprise any combination of one or more types of networks; and/or utilize any combination of various types of transmission techniques and protocols.

As described herein, embodiments provide ESD protection in specific areas of the data center 20 at high-risk for static buildup, such as around processors, server racks, high-performance equipment, and/or the like. To this extent, the racks 22 (FIG. 2) of the data center 20 typically house ESD sensitive objects therein, which can benefit from localized ESD protection.

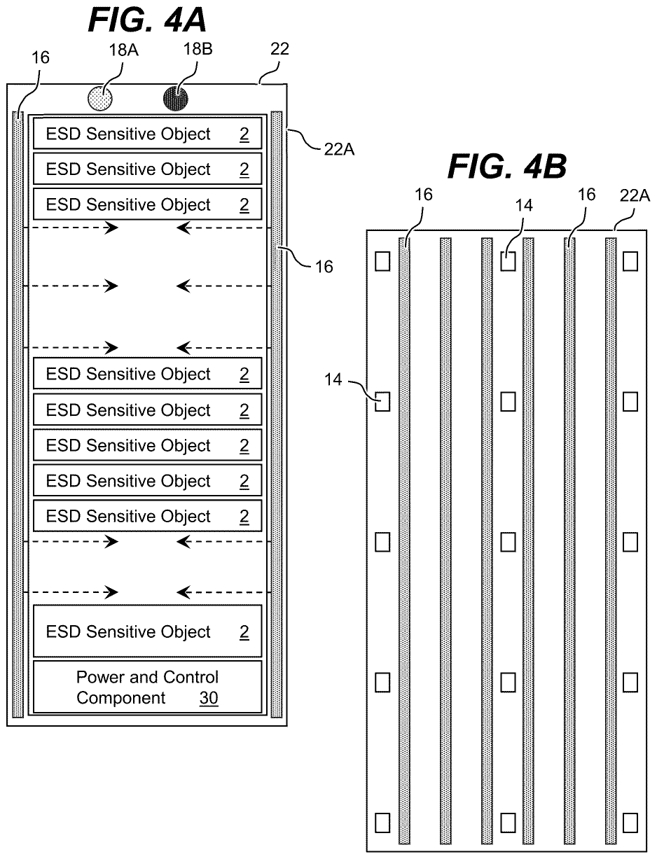

FIGS. 4A and 4B show a front view of an illustrative rack 22 and a side view of an internal surface of an illustrative side panel 22A of the rack 22 according to embodiments. In general, a rack 22 can be configured to hold a stack of ESD sensitive objects 2, such as various computing components. The rack 22 can include components for enabling wiring for electrical and/or data connections for the ESD sensitive objects 2, installation structures, such as slots and height adjustable shelves, that enable the selective installation of the ESD sensitive objects 2 therein, venting for providing or allowing airflow therethrough, door(s), and/or the like. These features of the rack 22 are not shown for clarity.

In embodiments, the rack 22 includes a standalone ESD protection system, which can include a power and control component 30 mounted therein, which itself may be an ESD sensitive object protected by the ESD protection system. In other embodiments, the electrostatic sensors 14 and ionizing light sources 16 can provide data and/or be operated by a centralized system, such as the data center control system 26 (FIG. 3). In the latter case, the power and control component 30 can enable communications with the centralized system.

As illustrated, the rack 22 can include one or more electrostatic sensors 14 and one or more ionizing light sources 16 mounted to one or more side panels 22A of the rack 22. Embodiments can include multiple electrostatic sensors 14 spaced along a height of the rack 22, each of which can acquire and provide electrostatic data for processing by a control component, such as the power and control component 30. Additionally, embodiments can include multiple ionizing light sources 16, each of which can extend over substantially all of a height of the side panel 22A, and can be spaced along a depth of the side panel 22A.

It is understood that the particular number of and arrangement of electrostatic sensors 14 and ionizing light sources 16 are only illustrative and various alternative configurations including differing numbers and/or sizes of ionizing light sources 16, differing numbers and/or sizes of electrostatic sensors 14, each having any of various arrangements, can be implemented in embodiments. In embodiments, the rack 22 can include one or more rows of three to five electrostatic sensors 14 spaced twelve to eighteen inches (thirty to forty-five cm) apart along the height, with one or more additional rows of electrostatic sensors 14 along the depth, if needed. However, it is understood that the number of and/or arrangement of electrostatic sensors 14 can vary significantly based on the application, the particular combination of types of electrostatic data acquired by the sensors, and/or the like.

In embodiments the rack 22 can include one or more features that prevent the ionizing light emitted by the ionizing light sources 16 from leaving an interior of the rack. For example, the rack side panels 22A and/or door(s), can be fabricated from materials configured to absorb or reflect the ionizing light, thereby preventing the transmission of the ionizing out of the rack 22. Furthermore, embodiments can include multiple ionizing radiation sources 16 vertically aligned, each of which is separately operable by a control component, such as the power and control component 30. The control component can only operate ionizing radiation sources 16 for which an ESD sensitive object 2 is located adjacent thereto (e.g., based on an input from a sensor indicating the presence or absence of an object). In this manner, less ionizing light can be generated to protect a partially filled rack 22.

In embodiments, the rack 22 includes one or more ESD protection I/O devices 18A, 18B. Embodiments of the rack 22 can include one or more sensors for acquiring data indicating a presence or absence of an ESD sensitive object 2 in a particular location. In embodiments, the rack 22 can include a human sensor 18A, such as a proximity sensor, motion detector, sensor indicating a door has been opened, and/or the like, which is configured to detect a presence of a human. In response to data acquired by the human sensor 18A indicating the presence of a human, the ESD protection system can turn off the ionizing light sources 16, if necessary, and enter an operating mode in which the ionizing light sources 16 are not turned on. In embodiments, the rack 22 can include one or more local output devices 18B, which can provide information regarding an operability, an operating status, an alert condition, and/or the like, of the ESD protection system for use by a local user. Illustrative local output devices 18B include a visible light source, a speaker for emitting an audible output, a wireless communication device for sending output data for processing on another computing device, and/or the like. Illustrative ESD protection I/O devices also include I/O devices, such as a touchscreen, and/or the like.

In embodiments, the I/O devices 18A, 18B can enable the power and control component 30 to generate a warning to a local user that the supplemental ESD protection has been temporarily disabled. In embodiments, the ESD protection system (e.g., the power and control component 30) can continue to receive and monitor the electrostatic data from the electrostatic sensor(s) 14 and determine whether a risk of an ESD event exceeds a predetermined level. In response to the risk exceeding the predetermined level, the ESD protection system can generate an alert for the local user. In more particular embodiments, the alert can comprise an audible alert as the user may be focused on performing one or more actions and not on a visible output device. The alert can enable the user to take action to prevent an ESD event. For example, the user can pause the action(s), and allow the ESD protection system to reduce the risk of an ESD event, e.g., by shutting a door to the rack 22, moving away from the rack 22, and/or the like. In embodiments, the power and control component 30 can subsequently provide information to the user that the ESD event risk has been returned to a safe level.

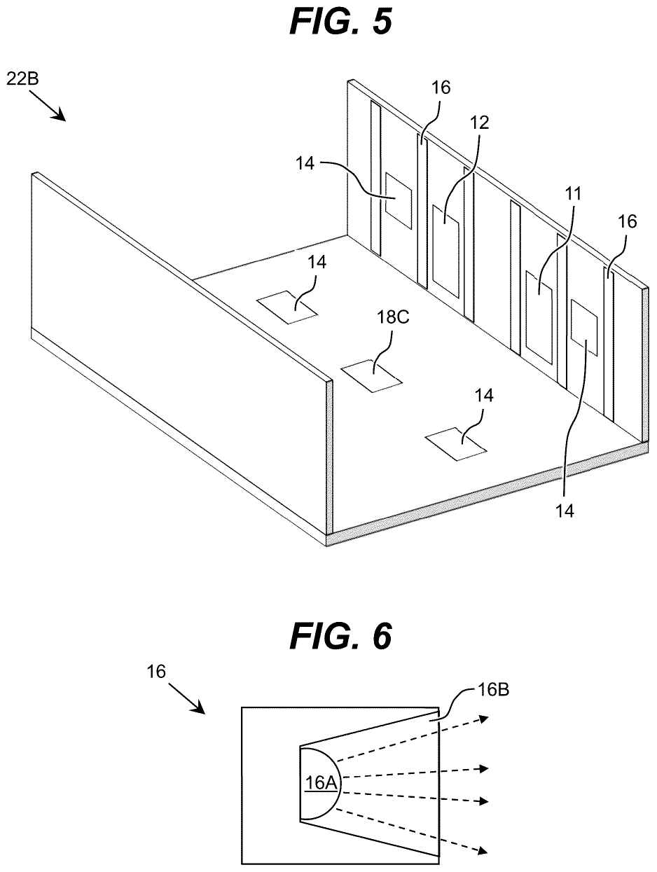

Embodiments of an ESD protection system described herein can be portable and/or modular. To this extent, embodiments of the rack 22 can be configured with a portable or modular ESD protection system for protecting an individual ESD sensitive component 2. For example, FIG. 5 shows an illustrative component shelf 22B for a rack, which includes an ESD protection system according to embodiments. In this case, the shelf 22B can include a control component 12, a power component 11, one or more electrostatic sensors 14, one or more ionizing radiation sources 16, a component sensor 18C, and/or the like, each of which can operate as described herein in order to protect a component located on the shelf 22B from electrostatic discharge.

The shelf 22B can be sized and configured for use in any location of any of a plurality of racks 22, thereby providing a portable solution for protecting a particularly sensitive ESD sensitive object. In other embodiments, a portable ESD protection system can be configured for placement in any area in which ESD protection is required or desired.

In embodiments, an ionizing radiation source 16 is configured to restrict a direction in which the ionizing radiation is emitted, e.g., to prevent harming a user, allow for a lower power emission, etc. To this extent, FIG. 6 shows an illustrative ionizing light source configuration according to embodiments. In this case, an ionizing light emitter 16A, such as an LED, can be mounted within a recess 16B, which restricts a spread of the ionizing light emitted by the ionizing light emitter 16A. In embodiments, the recess 16B can be filled with a transparent material to protect the corresponding ionizing light emitter(s) 16A from contamination. Illustrative materials include fused quartz, UVC silicones, clear acrylic, and/or the like. In embodiments, an external surface of the transparent material can be configured to further direct the ionizing light in a desired direction.

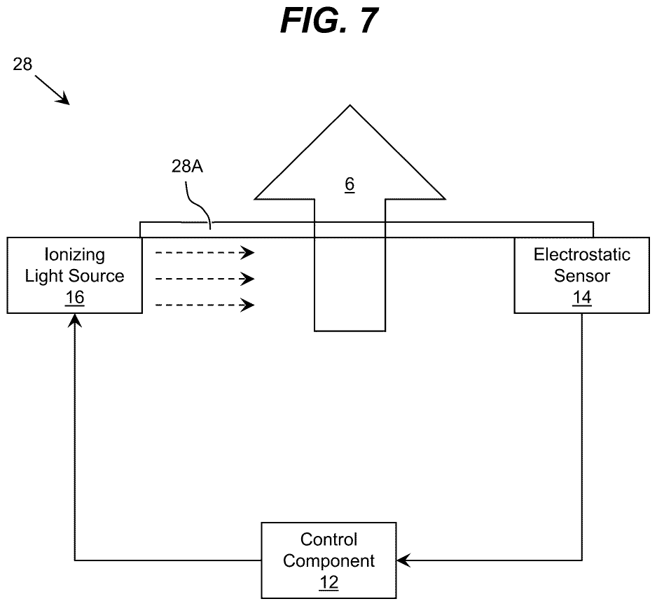

In embodiments, an ESD protection system described herein can be located in other locations of the data center 20 (FIG. 2), which may not be adjacent to an ESD sensitive object. In embodiments, an ESD protection system can be implemented within a ventilation system of a data center 20. For example, FIG. 7 shows an illustrative vent 28 including an ESD protection system according to embodiments. The vent 28 can comprise a screen 28A through which air 6 passes into the data center 20. The vent 28 can include one or more electrostatic sensors 14 and one or more ionizing light sources 16 mounted to a bottom of the screen 28A, e.g., within the duct, using any solution. A control component 12 (e.g., mounted to the bottom of the screen along with a power source or remotely located), can control operation of the ionizing light source(s) 16 based on electrostatic data provided by the electrostatic sensor(s) 14 as described herein. In embodiments, the components of the ESD protection system are mounted to the bottom of the screen 28A such that the vent 28 can be installed in a standard manner without requiring modification to existing configurations. In embodiments, the ESD protection system is configured to only operate when air 6 is passing through the screen 28A.

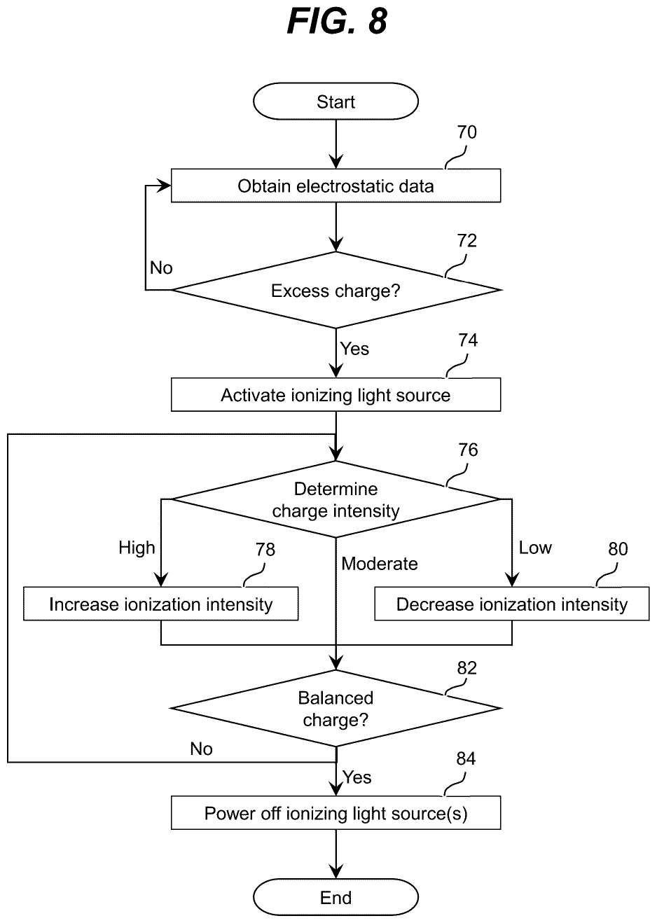

FIG. 8 shows an illustrative process for protecting an ESD sensitive object from an ESD event, which can be implemented by an ESD protection control component described herein, according to embodiments. In action 70, the control component can obtain electrostatic data from one or more electrostatic sensors. In action 72, the control component can process the electrostatic data to determine whether the electrostatic charge is too high (e.g., a risk of an ESD event exceeds an acceptable level). If not, the control component can take no action and continue monitoring.

If the electrostatic charge is determined to be too high, in action 74, the control component can activate one or more ionizing radiation light sources to lower the electrostatic charge. In action 76, the control component can again determine an electrostatic charge intensity to determine whether it is within one of three ranges. In the event the charge intensity remains too high (e.g., above the acceptable level), in action 78, the control component can increase an intensity of the ionizing light to attempt to more quickly lower the charge intensity. When the charge intensity is determined to be within a low range, in action 80, the control component can decrease an intensity of the ionizing light. Otherwise, when the charge intensity is determined to be within a moderate range, the control component can keep the intensity of the ionizing light unchanged.

The thresholds defining each of the ranges can be adjusted based on a particular application for the ESD control system. In embodiments, the ranges can correspond to an industry standard for an ESD sensitive environment. In embodiments, the moderate range can correspond to approximately ±500V to approximately ±2 kV, with the low range being below approximately ±500V and the high range being above approximately ±2 kV.

In action 82, the control component can determine whether the charge is balanced within the ambient environment. For example, the control component can evaluate electrostatic data from various electrostatic sensors to determine whether there is any significant variation within the area being monitored. If significant variation remains, the control component can continue to monitor the charge intensity while keeping the ionizing light source(s) on. Once the charge intensity is sufficiently low and balanced, in action 84, the control component can power off the ionizing light source(s). Subsequently, the process can start over, e.g., immediately, after a predetermined delay, and/or the like.

It is understood that the process shown in FIG. 8 is only illustrative. Embodiments of the ESD protection control component can implement processes with any of various alternative actions. In embodiments, the control component can generate an error condition and turn off the ionizing light source(s) in response to the charge intensity continuing to be too high in action 76 for a period of time exceeding a maximum period. In this case, such a situation may be indicative of malfunctioning sensors and/or ionizing light sources, ineffective configuration of the ESD protection system, an environmental issue causing the excessive intensity, and/or the like, any of which should be evaluated by a user 4 for possible actions.

In embodiments, the control component can operate the ionizing light sources using alternative data indicative of a risk of an ESD event. For example, the control component can activate the ionizing light sources in response to a humidity level dropping below a threshold. Furthermore, the control component can adjust an intensity of the ionizing light based on how low the humidity level drops below the threshold. It is understood that any of various combinations of ESD-related data can be used to operate the ionizing light sources.

Additionally, in embodiments, the control component can operate the ionizing light sources periodically. For example, even when data acquired for an environment does not indicate a risk of an ESD event, the control component can activate the ionizing light sources to emit ionizing light for a predetermined time period after a predetermined amount of time has passed since the ionizing light sources have been activated.

As used herein, unless otherwise noted, the term “set” means one or more (i.e., at least one) and the phrase “any solution” means any now known or later developed solution. The singular forms “a,” “an,” and “the” include the plural forms as well, unless the context clearly indicates otherwise. Additionally, the terms “comprises,” “includes,” “has,” and related forms of each, when used in this specification, specify the presence of stated features, but do not preclude the presence or addition of one or more other features and/or groups thereof.

As also used herein, a layer is a transparent layer when the layer allows at least ten percent of radiation having a target wavelength, which is radiated at a normal incidence to an interface of the layer, to pass there through. Furthermore, as used herein, a layer is a reflective layer when the layer reflects at least ten percent of radiation having a target wavelength, which is radiated at a normal incidence to an interface of the layer. In an embodiment, the target wavelength of the radiation corresponds to a wavelength of radiation emitted or sensed (e.g., peak wavelength+/−five nanometers) by an active region of an optoelectronic device during operation of the device. For a given layer, the wavelength can be measured in a material of consideration and can depend on a refractive index of the material.

It is understood that, unless otherwise specified, each value is approximate and each range of values included herein is inclusive of the end values defining the range. Terms of degree such as “generally,” “substantially,” “about,” and “approximately” as used herein mean a reasonable amount of deviation of the modified term such that the end result is not significantly changed. For example, these terms can be construed as including a deviation of at least +/−0.5% of the modified term if this deviation would not negate the meaning of the word it modifies. In a more particular example, the term “approximately” is inclusive of values within +/−ten percent of the stated value, while the term “substantially” is inclusive of values within +/−five percent of the stated value when these deviations would not negate the meaning of the word each term modifies.

The foregoing description of various aspects of the invention has been presented for purposes of illustration and description. It is not intended to be exhaustive or to limit the invention to the precise form disclosed, and obviously, many modifications and variations are possible. Such modifications and variations that may be apparent to an individual in the art are included within the scope of the invention as defined by the accompanying claims.

What is claimed is:

1. An electrostatic discharge (ESD) protection system comprising:
an electrostatic sensor configured to be associated with an ESD sensitive object;
a control component configured to receive electrostatic data acquired by the electrostatic sensor and determine a likelihood of an ESD event using the electrostatic data; and
an ionizing light source configured to emit ionizing light directed in an area near the ESD sensitive object, wherein the control component is configured to activate the ionizing light source to emit the ionizing light in response to a determination that the likelihood of the ESD event exceeds a predetermined threshold.

2. The ESD protection system of claim 1, wherein the electrostatic data acquired by the electrostatic sensor comprises data corresponding to a measurement of an electric field strength or a surface voltage related to a static charge.

3. The ESD protection system of claim 1, wherein the electrostatic data acquired by the electrostatic sensor comprises data corresponding to a humidity and/or a temperature of an ambient environment.

4. The ESD protection system of claim 1, wherein the electrostatic data acquired by the electrostatic sensor comprises data corresponding to one or more of an air ionization level, an electrostatic potential distribution, or a charge decay rate, for an ambient environment.

5. The ESD protection system of claim 1, wherein the ionizing light source is configured to emit ionizing light that is directed onto a surface of the ESD sensitive object.

6. The ESD protection system of claim 1, wherein the ionizing light comprises ultraviolet light having a peak wavelength in the ultraviolet-C range of wavelengths and/or in the near ultraviolet light range of wavelengths.

7. The ESD protection system of claim 1, further comprising a fan, wherein the control component is further configured to operate the fan to reduce the likelihood of an ESD event.

8. A data center comprising:
a data center control system configured to manage operation of the data center and maintain an environment within the data center; and
a plurality of data center racks, at least one of the plurality of data center racks including:
a plurality of shelves, each shelf configured to hold at least one ESD sensitive computing component;
at least one electrostatic sensor associated with at least one of the plurality of shelves, wherein the at least one electrostatic sensor is configured to acquire electrostatic data; and
an ionizing light source configured to emit ionizing light directed in an area near the at least one of the plurality of shelves, wherein an ESD control component is configured to determine a likelihood of an ESD event using the electrostatic data and activate the ionizing light source to emit the ionizing light in response to a determination that the likelihood of the ESD event exceeds a predetermined threshold.

9. The data center of claim 8, wherein the ESD control component comprises a component of the data center control system.

10. The data center of claim 8, wherein the ESD control component is located on the at least one of the plurality of data center racks.

11. The data center of claim 8, wherein the at least one of the plurality of data center racks includes a plurality of ionizing light sources configured to emit ionizing light along substantially all of a height of the at least one of the plurality of data center racks.

12. The data center of claim 8, wherein the at least one of the plurality of data center racks includes a plurality of electrostatic sensors spaced along a height of the at least one of the plurality of data center racks.

13. The data center of claim 8, wherein the at least one of the plurality of data center racks further includes at least one feature configured to prevent ionizing light from leaving an interior area of the at least one of the plurality of data center racks.

14. The data center of claim 8, wherein the at least one of the plurality of data center racks further includes a local output device, wherein the ESD control component is configured to operate the local output device to provide information regarding an operability, an operating status, and/or an alert condition, of the ionizing light source.

15. The data center of claim 8, wherein at least one of the plurality of shelves includes the at least one electrostatic sensor and the ionizing light source mounted thereto.

16. The data center of claim 8, further comprising a ventilation system including a plurality of vents, wherein at least one vent includes a screen and at least one vent electrostatic sensor and at least one vent ionizing light source mounted on a duct side of the screen, wherein the ESD control component is further configured to process electrostatic data acquired by the at least one vent electrostatic sensor and activate the at least one vent ionizing light source to emit ionizing light based on the processed electrostatic data.

17. An electrostatic discharge (ESD) protection system for an environment including an ESD sensitive object, the ESD protection system comprising:
a plurality of ionizing light sources, wherein each of the plurality of ionizing light sources is configured to emit ionizing light directed in an area of the environment; and
a control component configured to operate the plurality of ionizing light sources to reduce risk of an ESD event in the environment.

18. The ESD protection system of claim 17, further comprising at least one electrostatic sensor configured to acquire electrostatic data for a monitored area of the environment, wherein the control component is configured to determine a likelihood of an ESD event in the monitored area of the environment using the electrostatic data and activate at least one of the plurality of ionizing light sources to emit the ionizing light in an area associated with the monitored area in response to a determination that the likelihood of the ESD event exceeds a predetermined threshold.

19. The ESD protection system of claim 17, wherein the environment comprises a data center, and wherein the plurality of ionizing light sources includes a plurality of data center rack ionizing light sources configured to emit ionizing light into at least one data center rack of the data center.

20. The ESD protection system of claim 19, wherein the plurality of data center rack ionizing light sources includes at least one ionizing light source mounted to a shelf of the data center rack.

21. The ESD protection system of claim 17, wherein the control component is configured to turn off the plurality of ionizing light sources in response to an indication of a presence of a human.
